(19) United States
(12) Patent Application Publication
(10) Pub. No.: US 2024/0372530 A1
(43) Pub. Date: Nov. 7, 2024

(54) SYSTEMS AND METHODS FOR ABSORPTION TUNING FOR TOTAL WAVE ABSORPTION AND REFLECTION

(71) Applicant: Toyota Motor Engineering & Manufacturing North America, Inc., Plano, TX (US)

(72) Inventors: Xiaopeng Li, Ann Arbor, MI (US); Taehwa Lee, Ann Arbor, MI (US); Ziqi Yu, Ann Arbor, MI (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 18/312,015

(22) Filed: May 4, 2023

(51) Int. Cl. H03H 9/56; H03H 9/02

(52) U.S. Cl. CPC H03H 9/564; H03H 9/02015; H03H 2009/155

(57) ABSTRACT

System, methods, and other embodiments described herein relate to tuning an absorption system based on an exceptional point for a shunted mechanical resonator of the absorption system. In one embodiment, the absorption system includes a first mechanical resonator having a beam connected to a body that is subject to a flexural wave. The first mechanical resonator has a latent absorption. The absorption system includes a first electrical resonator that includes a piezoelectric device, bonded to the beam, that generates electricity in response to the flexural wave propagating through the body. The absorption system also includes a shunting circuit connected to the piezoelectric device and tuned based on a calculated exceptional point for the absorption system. The shunting circuit alters an absorption of the first mechanical resonator and controls a voltage and current shunted to the piezoelectric device to absorb the flexural wave.

### TECHNICAL FIELD

The subject matter described herein relates, in general, to absorption systems to absorb a flexural wave, and more particularly, to systems and methods for absorbing flexural waves by tuning an absorption system towards the exceptional point for the absorption system.

### BACKGROUND

Resonators are used in a variety of industries and for a variety of purposes. For example, bending or flexural waves that propagate through a structure, such as a vehicle body, may damage the structure or generate unwanted noise in the surrounding environment. In this example, a resonator attached to the structure absorbs the flexural waves, thus negating the adverse effects of the propagating wave.

In another example, a resonator may be part of an electrical system. A resonator may be used to detect or generate a precise frequency for sensing, signal processing, and/or digital encoding. As a specific example, a system may rely on sensor data to execute some functionality, such as detecting conditions in a surrounding environment. For the system to perform as intended, the sensor data should convey accurate environmental data. However, if there is too much noise in the sensor data, the system may improperly perform or perform below a desired level. In this example, a resonator may filter out noise such that the system receives and acts upon sensor data with reduced noise.

### SUMMARY

In one embodiment, example systems and methods relate to a manner of improving the tuning of a wave absorption system to perfectly absorb or perfectly reflect a target flexural wave traveling through a body to which the absorption system is attached.

In one embodiment, a system for absorbing a flexural wave is disclosed. The system includes a first mechanical resonator having a beam connected to a body that is subject to a flexural wave. The first mechanical resonator has a latent absorption. The system includes a first electrical resonator that includes a piezoelectric device, bonded to the beam, which generates electricity in response to the flexural wave propagating through the body. The system also includes a shunting circuit connected to the piezoelectric device and tuned based on a calculated exceptional point for the system. The shunting circuit alters an absorption of the first mechanical resonator and controls a voltage and current shunted to the piezoelectric device to absorb the flexural wave.

In one embodiment, a system includes a first mechanical resonator having a beam connected to a body that is subject to a flexural wave. The system also includes a first electrical resonator that includes a piezoelectric device, bonded to the beam, which generates electricity in response to the flexural wave propagating through the body. The system also includes a shunting circuit connected to the piezoelectric device and tuned based on a calculated exceptional point for the system. The shunting circuit alters an absorption of the first mechanical resonator towards perfect absorption or perfect reflection and controls a voltage and current shunted to the piezoelectric device to absorb the flexural wave.

In one embodiment, a method includes calculating an exceptional point for a system that includes a first mechanical resonator shunted by a first electrical resonator. The first system is placed on a body that is subject to a flexural wave. The first mechanical resonator has a latent absorption. The method also includes altering a wave absorption coefficient of a first electrical resonator coupled to the first mechanical resonator by setting inductor and resistor values of a shunting circuit of the first electrical resonator based on a calculated exceptional point for the first mechanical resonator. The method further includes generating, via the shunting circuit, electricity to totally absorb or totally reflect the flexural wave in the body.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates an example mass-spring-damper system that represents the functionality of the absorption system tuned based on an exceptional point of an LR-shunted mechanical resonator.

FIG. 2 illustrates an implementation of an absorption system tuned based on the exceptional point of the LR-shunted mechanical resonator.

FIG. 3 illustrates one embodiment of a shunting circuit of the absorption system tuned based on the exceptional point of the LR-shunted mechanical resonator.

FIG. 4 illustrates an example graph of an exceptional point for an LR-shunted mechanical resonator.

FIG. 5 is an example graph depicting the absorption spectrum of an absorption system tuned based on the exceptional point for the LR-shunted mechanical resonator.

FIG. 6 illustrates an example synthetic inductor of the absorption system.

FIG. 7 illustrates a flowchart of a method that is associated with absorbing a flexural wave.

FIG. 8 illustrates one embodiment of the absorption system having multiple mechanical resonators.

FIGS. 9A and 9B are example graphs depicting the absorption spectra of an absorption system tuned based on the exceptional point for the LR-shunted mechanical resonator.

FIG. 10 is an example graph depicting an observed absorption spectrum of an absorption system tuned based on the exceptional point for the LR-shunted mechanical resonator.

### DETAILED DESCRIPTION

Systems, methods, and other embodiments associated with improving the absorption of a flexural wave traveling through a rigid body are disclosed. The disclosed embodiments provide numerous advantages over conventional approaches to absorbing vibrations and flexural waves. For example, metamaterials and metasurfaces may be used to control acoustic and elastic waves at a deep subwavelength scale. In one example, total internal-reflection elastic metasurfaces or metamaterials have been proposed to create sound barriers at deep subwavelength scales to isolate noise sources. A perfect absorber could totally absorb the incoming waves at the deep subwavelength scale by balancing the internal damping and leakage rates. However, perfect wave absorption is difficult due to a lack of tunability of the absorption system. As such perfect wave absorption is typically only seen at single frequencies. As a specific example, passive damping materials such as rubbers, polymeric foams, or elastomers have been used to absorb flexural waves. However, such passive absorbers lack tunability and are not adaptable to the change of flexural waves acting on the mechanical structure. Furthermore, solutions of this type can add a considerable amount of weight to a target system.

Mechanical resonators may also be used. However, mechanical resonators have intrinsic damping. This intrinsic damping prevents the mechanical resonator from perfectly absorbing or perfectly reflecting a flexural wave propagating through a rigid structure. As such, it is hard to realize total reflection or total absorption in a metamaterial or metasurface in a tunable manner without precisely controlling the damping coefficient of the mechanical resonator.

Accordingly, the present specification describes a non-Hermitian system that tunes an initially imperfect absorber to a perfect reflector or a perfect absorber. The absorption system of the present specification includes a shunted mechanical resonator on a body. An electrical resonator of the absorption system is tuned based on an exceptional point of the shunted mechanical resonator of the absorption system to adjust the latently imperfect absorption system to totally reflect or totally absorb a propagating flexural wave.

Specifically, the exceptional point for the isolated absorption system is calculated before the absorption system is placed on the rigid structure for which it is to absorb flexural waves. With the exceptional point calculated, the absorption system is placed on the body. As described above, the absorption system includes a shunting circuit that includes an inductor and a resistor (LR) circuit. The LR circuit is coupled to the mechanical resonator through a piezoelectric device. The LR circuit is tuned to the calculated exceptional point. By tuning the LR circuit, perfect absorption is achieved near the exceptional point of the mechanical resonator. As such, a latently imperfect absorber/reflector is converted into either a system that totally reflects the flexural wave or that totally absorbs the flexural wave based on the tuned resistance of the LR circuit. While other systems may tune a wave absorption system, such systems do not tune the absorption system to the exceptional point of the mechanical resonator. Tuning the absorption system based on the exceptional point of the LR-shunted mechanical resonator results in a broader absorption spectrum, thus providing a more efficient absorption system. The absorption system of the present specification that exhibits total reflection or total absorption may be implemented in a number of technical fields, including photonics, electrical circuits, mechanics, and acoustics.

As used in the present specification and the appended claims, the term “exceptional point” refers to a point where both eigenfrequencies and eigenstates coalesce, giving rise to unidirectional zero reflection or other unidirectional behaviors, perfect absorption, and enhanced second-order and higher-order sensitivities.

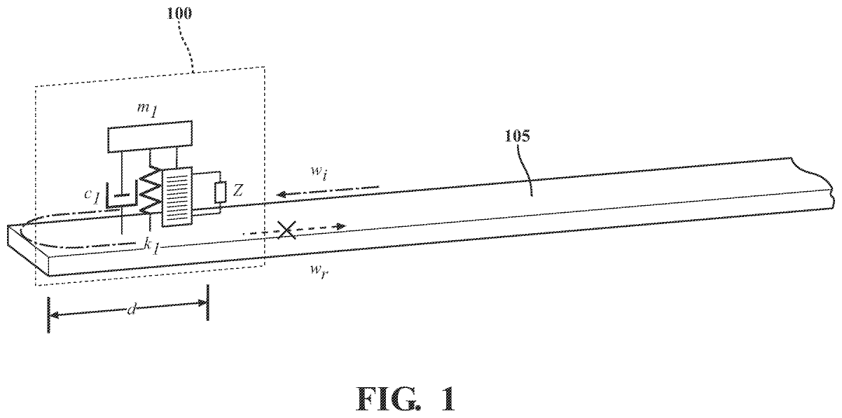

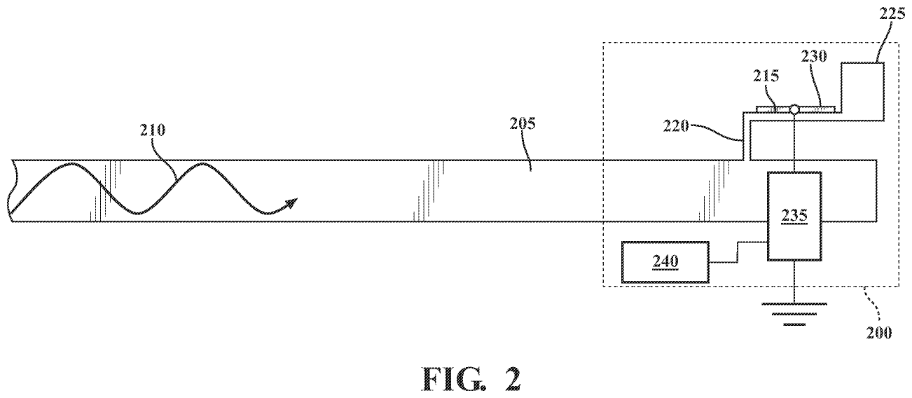

FIG. 1 illustrates an example mass-spring-damper system 100 that represents the functionality of the absorption system tuned based on the exceptional point of the LR-shunted mechanical resonator by an electrical resonator. As described above, the absorption system that is represented by the mass-spring-damper system 100 may be positioned on a body 105. The body 105 is 1) subject to flexural waves and/or 2) to be used as a sensor. As depicted in FIG. 1, the mass-spring-damper system 100, or the absorption system depicted in FIG. 2, may be positioned near a free end of the body 105. While FIG. 1 depicts a free-end boundary condition, in other examples, the body 105 may not have a free-end boundary condition, in which case the absorption system may be placed at any location along the body 105.

For simplicity, the mass-spring-damper system 100 is depicted as being disposed at a distance, d, away from a free end of the body 105. The mass-spring-damper system 100 includes a mass element, m₁, coupled to the body 105 via a spring element having a spring constant, k₁. The mass-spring-damper system 100 has an intrinsic damping coefficient, c₁. For purposes of illustration in the present application, the body 105 is aluminum and has dimensions b×h=12.7 millimeters (mm)×3.1 mm, m₁ is 0.96 grams (g), k₁ is 91 kilonewtons per meter (kN/m), and c₁ is 0.0104*\sqrt{k₁m₁}. As described herein, the absorption system is shunted with an impedance Z. i.e., an inductance and resistance (LR) circuit.

As described below, the shunting circuit of the absorption system includes an inductor and a resistor, which are tuned to the exceptional point of the LR-shunted mechanical resonator. Doing so converts the imperfect absorbing system to an absorption system that totally absorbs or totally reflects the flexural wave based on how the inductor and resistor are tuned. Given that the tuning is based on the exceptional point of the LR-shunted mechanical resonator, the absorption spectrum of the exceptional point-based absorption system has a broader width than an absorption system tuned without considering the exceptional point.

FIG. 2 illustrates an implementation of an absorption system 200 that is tuned based on an exceptional point of an LR-shunted mechanical resonator. The absorption system 200 includes multiple components. Some of the possible elements of the disclosed absorption system 200 are shown in FIG. 2 and will be described along with subsequent figures. For simplicity and clarity of illustration, where appropriate, reference numerals have been repeated among the different figures to indicate corresponding or analogous elements. In addition, while the discussion outlines numerous specific details to provide a thorough understanding of the embodiments described herein, those of ordinary skill in the art will understand that the embodiments described herein may be practiced using various combinations of these elements. It should be understood that in various embodiments, the absorption system 200 may not include all of the elements shown in FIG. 2. That is, the absorption system 200 may have any combination of the various elements shown in FIG. 2. Further, the absorption system 200 may have other elements in addition to those shown in FIG. 2.

Returning to FIG. 2, the absorption system 200 includes a mechanical resonator. The mechanical resonator includes a beam 215 connected to a body 205 that is subject to a flexural wave. While FIG. 2 depicts the body 205 as having a particular structure, the body 205 may be a pipe or other structure subject to transmitting flexural waves 210. As described above, the flexural wave 210 propagates through the body 205 and may damage the body 205 if not dissipated. The mechanical resonator, in part, absorbs the flexural wave.

The mechanical resonator includes a base member 220 that couples the beam 215 to the body 205 while maintaining the beam 215 at an elevated position away from the body 205. The mechanical resonator further includes a rigid mass component 225 attached at a distal end of the beam 215. As described above, this mechanical resonator has a latent absorption that neither totally reflects nor totally absorbs the flexural wave 210. Without accommodation, at least a portion of the flexural wave 210 will propagate past the absorption system 200. To convert the absorption system 200 from absorbing/reflecting less than all of the flexural wave 210 to a total absorber or total reflector, the absorption system 200 further includes an electrical resonator.

The electrical resonator includes a piezoelectric device 230. As depicted in FIG. 2, the piezoelectric device 230 may be connected to a first side of the beam 215. The piezoelectric device 230 may include a patch of piezoelectric material that converts mechanical energy into electrical energy. When mechanical stresses are applied to the piezoelectric device 230, the piezoelectric device 230 generates electrical charges. By contrast, when a voltage is applied to the piezoelectric device 230, the piezoelectric device 230 generates a mechanical strain. As such, the piezoelectric device 230, which is bonded to the beam 215, generates electricity in response to the flexural wave 210 propagating through the body 205.

The electrical resonator also includes a shunting circuit 235 connected to the piezoelectric device 230. The shunting circuit 235, in combination with the piezoelectric device 230, absorbs the flexural wave 210 as it propagates through the body 205. As described above, the shunting circuit 235 is tuned to a calculated exceptional point for the absorption system 200. i.e., the LR-shunted mechanical resonator. That is, an LR-shunted mechanical resonator includes an exceptional point, which is defined as a point where eigenfrequencies and eigenstates coalesce, giving rise to unidirectional zero reflection or other unidirectional behaviors, perfect absorption, and enhanced second-order and higher-order sensitivities. As described below in connection with FIG. 4, the exceptional point for the LR-shunted mechanical resonator may be calculated by solving coupled second-order differential equations. With this exceptional point calculated, the shunting circuit 235, specifically the inductor and resistor of the shunting circuit 235, are tuned to close to this point.

The absorption system 200 may include a controller 240 to control one or more components of the shunting circuit 235 based on a calculated exceptional point for the LR-shunted mechanical resonator. For example, the controller 240 adjusts an inductance level of an inductor or a resistance level of a resistor of the shunting circuit 235 to achieve a desired resistance and inductance. As will be described below, the change to resistance dictates whether an imperfectly absorbing system totally reflects or totally absorbs a flexural wave 210, while a change to the inductance shifts the absorption spectrum.

Experiments indicate that when the inductor and the resistor of the shunting circuit 235 are tuned to this exceptional point, the otherwise imperfectly absorbing mechanical resonator is converted into a perfect absorber or a perfect reflector, depending on how the resistor of the shunting circuit 235 is adjusted. By tuning the shunting circuit 235 based on the exceptional point of the LR-shunted mechanical resonator, a broader absorption spectrum is exhibited, as compared to a shunting circuit 235 tuned to a non-exceptional point case.

As such, the shunting circuit 235 tuned to the calculated exceptional point for the LR-shunted mechanical resonator alters the absorption of the absorption system 200, specifically towards perfect absorption or perfect reflection. As such, as the flexural wave 210 propagates through the body 205 toward a distal end, as depicted in FIG. 2, the absorption system 200 completely or nearly completely absorbs the flexural wave 210 as it approaches the absorption system 200.

To execute the absorption effect, the piezoelectric device 230 generates an electric charge in response to the flexural wave 210. The shunting circuit 235, in electrical communication with the piezoelectric device 230, senses the movement that the flexural wave 210 causes in the body 205 based on the electric charges generated by the piezoelectric device 230. That is, the shunting circuit 235 controls a voltage and current shunted to the piezoelectric device 230 to absorb the flexural wave. Accordingly, in response to mechanical stress in the body 205 caused by the flexural wave 210 propagating through the body 205, the piezoelectric device 230 generates electrical energy, which is then dissipated by the shunting circuit 235, thereby effectively absorbing the flexural wave 210.

To consider a general case, we assume a point force F, due to an attached absorption system 200, is applied at x=X, which is located at a distance, d, away from the terminal end of the body 205. According to Euler's beam assumptions, the governing equation of the body 205 may be written as:

$$\\ \begin{matrix}D \frac{{\partial }^{{}_{} 4} w ( x , t )}{\partial {x}^{{}_{} 4}} - ρ A \frac{{\partial }^{{}_{} 2} w ( x , t )}{\partial {t}^{{}_{} 2}} = F ( t ) δ ( x - X ) & Equation ( 1 )\end{matrix}$$

In Equation (1), w, D, ρ, and A represent the displacement in the vertical direction, bending stiffness, mass density, and cross-section area of the body 205, respectively. If we choose the location of the point force as the origin such that X=0 and define μ=F/w as a point force attachment impedance and assume a time harmonic motion (i.e., w=W e^{iωt}) with the time harmonic term being dropped, the governing equation reads:

$$\\ \begin{matrix}D ( \frac{{d}^{{}_{} 4} W ( x )}{{dx}^{{}_{} 4}} - {k}^{{}_{} 4} ( x ) ) = μ W ( X ) δ ( x - X ) & Equation ( 2 )\end{matrix}$$

In Equation (2), k is the flexural wavenumber defined as k⁴=ω² ρA/D and ω is the angular frequency. From these equations, the reflection coefficient, R, may be found using the following equation:

$$\\ \begin{matrix}R = {R}_{i} + {B}_{4} \frac{1 + {R}_{i} + {R}_{n}}{{m}_{x} - g ( 0 )} & Equation ( 3 )\end{matrix}$$

In Equation 3, Rᵢ=−ie^{-2ikd}, Rₙ=(1−i)e^{-kd}e^{-ikd},

$$\\ {B}_{4} = - {e}^{{}_{} - ikd} ( ( 1 + i ) {e}^{{}_{} - kd} + \frac{{ie}^{{}_{} ikd} + {e}^{{}_{} - ikd}}{2} ) ,$$

mₓ=2Dk³/μ, and g(x)=2Dk³G(x) with G(x) being the Green's function.

The below equation gives the absorption coefficient:

$$\\ \begin{matrix}α = 1 - {\vert R \vert}^{2} & Equation ( 4 )\end{matrix}$$

A lumped model for a mechanical resonator with mass, m₁, spring constant k₁, and damping coefficient c₁ attached at x=0, as shown in FIG. 2, is used to theoretically analyze the absorption system 200. The governing equation for this system is written as:

$$\\ \begin{matrix}- {m}_{1} {ω}^{{}_{} 2} Y + {k}_{1} ( Y - W ( 0 ) ) + i ω {c}_{1} ( Y - W ( 0 ) ) = 0 & Equation ( 5 )\end{matrix}$$

In Equation (5), Y represents the vertical displacement of the resonator. Following the previously defined point force impedance, μ=F/w, the expression of the attached impedance is therefore obtained as:

$$\\ \begin{matrix}μ = {m}_{1} {ω}^{{}_{} 2} \frac{{k}_{1} + i ω {c}_{1}}{{k}_{1} + i ω {c}_{1} - {m}_{1} {ω}^{{}_{} 2}} & Equation ( 6 )\end{matrix}$$

For the mechanical resonator's fixed mass and spring constant, perfect absorption could be achieved by optimizing the damping coefficient and the resonator location, d.

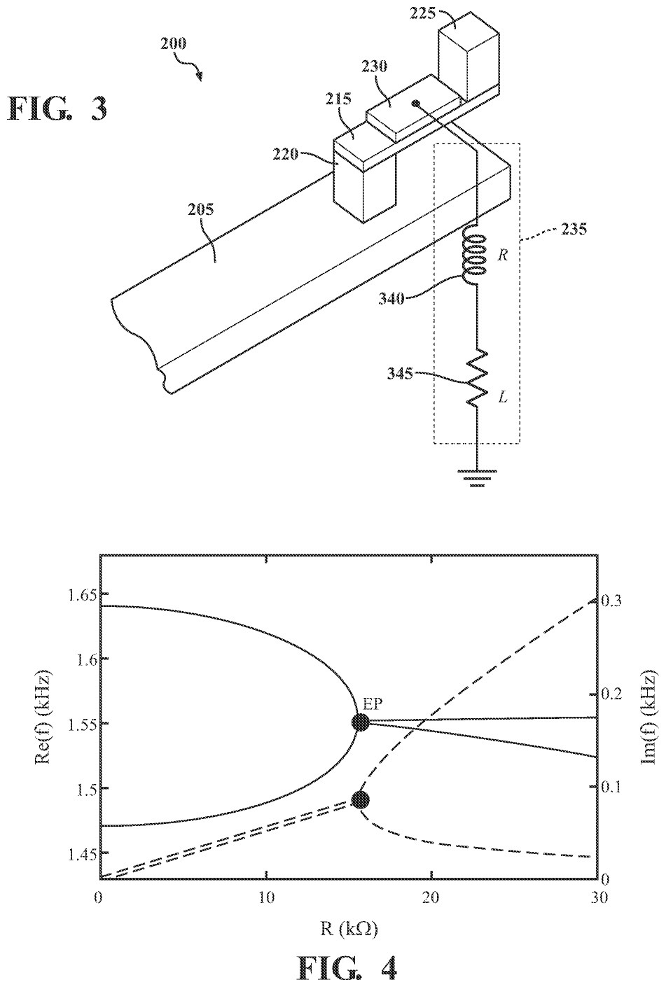

FIG. 3 illustrates one embodiment of a shunting circuit 235 of the absorption system that is tuned towards the exceptional point of the absorption system, i.e., the LR-shunted mechanical resonator. As described above, the shunting circuit 235 includes an inductor 340 and a resistor 345 connected in series to increase the wave absorption coefficient of the electrical resonator. As such, the shunting circuit 235, in conjunction with the piezoelectric device 230, forms an equivalent of a resistor-inductor-capacitor (RLC) circuit that can achieve electrical resonance.

Tuning the shunting circuit 235 includes tuning a value of the resistor 345 based on the exceptional point of the mechanical resonator. The resistance value of the resistor 345 determines whether the latently imperfect absorption system 200 tends towards perfect or total absorption or perfect or total reflection. Specifically, the resistor 345 having a first resistance value alters the absorption system 200 to totally reflect the flexural wave. The resistor 345 having a second resistance value that is greater than the first resistance value alters the absorption system 200 to totally absorb the flexural waves. In a particular example given the parameters of a system described above regarding the mass, spring constant, and dimensions of the body, the first resistance value that results in an absorption system 200 that totally reflects the flexural wave may be 100 ohm. By comparison, the second resistance value that results in an absorption system 200 that totally absorbs the flexural wave may be 3.6 kiloohms.

In addition to adjusting the resistance value of the shunting circuit 235, the controller 240 may alter the inductor 340 value to alter the absorption spectrum. Specifically, the controller 240 adjusts the inductor value to align a frequency peak of an altered absorption spectrum with a frequency peak of a latent absorption spectrum of the passive mechanical resonator.

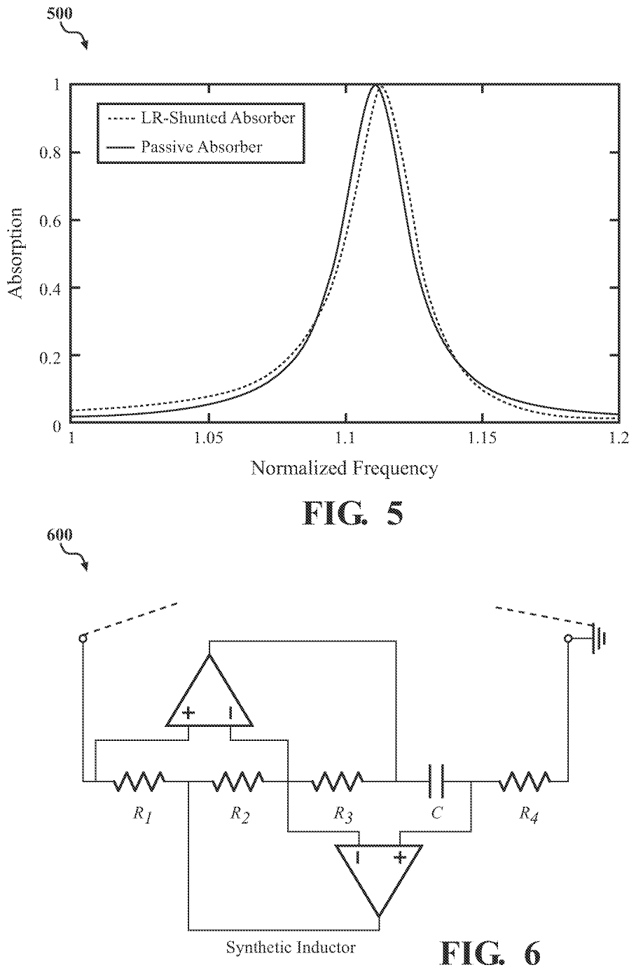

The shunting circuit 235 may be implemented as an analog circuit or a digital, adjustable circuit. In one example, the shunting circuit 235 includes a synthetic inductor as shown in FIG. 6. As such, the absorption system 200 can be adjusted such that the inherent imperfection in the absorption of flexural waves by a passive mechanical resonator is replaced with the total reflection or absorption of the flexural waves.

FIG. 4 illustrates an example graph 400 of an exceptional point for an LR-shunted mechanical resonator. As described above, the exceptional point for the LR-shunted mechanical resonator identifies a point where eigenfrequencies and eigenstates coalesce, giving rise to unidirectional zero reflection or other unidirectional behaviors, perfect absorption, and enhanced second-order and higher-order sensitivities and may be determined as follows. Considering an elastic beam bonded with a piezoelectric patch connected to an external shunting circuit as depicted above in FIG. 3, a one degree-of-freedom (DOF), e.g., the fundamental mode, is utilized to characterize the mechanical structure. The body 205 in FIG. 3 may represent an excitation structure for testing the exceptional point of the LR-shunted mechanical resonator. Specifically, a Schrödinger-like equation for the mechanical structure is given by the following equation:

$$\\ \begin{matrix}i \frac{d}{dt} Ψ = H Ψ & Equation ( 7 )\end{matrix}$$

with the Hamiltonian defined as:

$$\\ \begin{matrix}H = [ \begin{matrix}0 & \sqrt{D} \\ \sqrt{D} & i Γ\end{matrix} ] & Equation ( 8 )\end{matrix}$$

In Equation (8), ψ is the transformation matrix defined as:

$$\\ \begin{matrix}Ψ = [ \begin{matrix}\sqrt{D} & 0 \\ 0 & iI\end{matrix} ] \overline{Y} & Equation ( 9 )\end{matrix}$$

In Equation (9), D=M⁻¹K and I′=−M⁻¹C, with M, C, and K being the mass, structural damping, and stiffness matrices of the LR-shunted absorption system 200. The eigenvalues of the LR-shunted mechanical resonator can be directly derived from the Hamiltonian. FIG. 4 depicts the calculated complex eigenfrequencies of the LR-shunted resonator as a function of the shunted resistance. As depicted in FIG. 4, when the resistance is small (e.g., R<R_{EP}), there are two distinct real positive eigenfrequencies, whereas the two imaginary positive eigenfrequencies are almost identical. At the exceptional point, R=R_{EP}, denoted by the circles, both the real and imaginary eigenfrequencies coalesce. For a resistance that is greater than the resistance at the exceptional point, i.e., R>R_{EP}, one of the real eigenfrequencies is almost constant, and the associated imaginary eigenfrequency is decreasing. The other real eigenfrequency is decreasing while the associated imaginary eigenfrequency increases. This indicates that coupled resonators can engineer the absorption spectra near the coalesced frequency.

Put another way, FIG. 4 clearly indicates that the eigenfrequencies have two branches. As resistance increases, the two branches of the eigenfrequencies converge at this single point for both real and imaginary eigenfrequencies. This collapsing point is referred to as the exceptional point. As such, by plotting the eigenfrequency variation with respect to the resistance and inductance as depicted in FIG. 4, an exceptional point for the LR-shunted mechanical resonator is determined and used as a basis for tuning the shunting circuit 235.

FIG. 5 is an example graph 500 depicting the absorption spectrum of an absorption system 200 that is tuned based on the exceptional point for the absorption system, i.e., the LR-shunted mechanical resonator. FIG. 5 indicates that an absorption system 200 with a shunting circuit 235 tuned towards the exceptional point of the LR-shunted mechanical resonator behaves similarly to a damped and passive mechanical resonator (i.e., without a shunting circuit). Specifically, the absorption spectrum of the absorption system 200 tuned towards the calculated exceptional point of the LR-shunted mechanical resonator, indicated by the dashed line in FIG. 5, is similar to the absorption spectrum of the passive absorber, indicated by the solid line in FIG. 5. As described above, absorption systems that are not tuned to the exceptional point have a narrower absorption spectrum. The present specification, by comparison, generates perfect absorption near the exceptional point, thus resulting in a broader absorption spectrum.

When the shunted mechanical resonator is considered, the point impedance may be written as:

$$\\ \begin{matrix}{μ}_{z} = ( {k}_{1} + i ω {c}_{1} ) ( 1 - {Γ}_{0} ) & Equation ( 10 )\end{matrix}$$

In Equation (0),

$$\\ {Γ}_{0} = \frac{{k}_{1} + i ω {c}_{1}}{{k}_{1} + i ω {c}_{1} - {m}_{1} {ω}^{{}_{} 2} + {k}_{1} {Γ}_{1}} ,$$

with and

$$\\ {Γ}_{1} = \frac{- {k}_{1}}{{k}_{2} + i ω R - L {ω}^{{}_{} 2}}$$

k₂=1/Cₚ with Cₚ being the intrinsic capacitance of the piezoelectric device 230 which can be calculated from Cₚ=Aₚε^{σ}/hₚ with Aₚ being the area of the electrode, hₚ the thickness of the piezoelectric device 230, and ε^{σ} the dielectric constants measured at constant stress.

FIG. 6 illustrates an example synthetic inductor 600 of the absorption system 200. A synthetic inductor 600 may be used in the shunting circuit 235 to reduce the size of the inductor and to provide additional tuneability to the inductance value by adjusting one of the resistors in the circuit. The synthetic inductor 600 includes two operational amplifiers, four resistors (R1-R4), and a capacitor (C). The inductance of the synthetic inductor 600 is calculated as, L=R₁R₃R₄C/R₂. To adjust the inductor, a trimmer may tune resistor R₁, while keeping other parameters fixed. In some examples, this trimmer could be replaced with a digital resistor programmed by the controller 240.

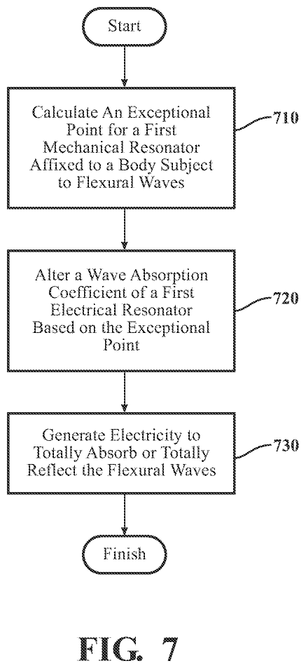

Additional aspects of the tuning of the absorption system 200 towards a calculated exceptional point for an LR-shunted mechanical resonator will be discussed in relation to FIG. 7. FIG. 7 illustrates a flowchart of a method 700 that is associated with absorbing a flexural wave. Method 700 will be discussed from the perspective of the absorption system 200 of FIGS. 2 and 3. While method 700 is discussed in combination with the absorption system 200, it should be appreciated that the method 700 is not limited to being implemented within the absorption system 200 but is instead one example of a system that may implement the method 700.

At operation 710, an exceptional point for an absorption system 200 that includes an LR-shunted first mechanical resonator that is placed, or is to be placed, on a body 205 that is subject to flexural waves is determined. As described above, the exceptional point may be calculated by first determining the eigenfrequencies for the LR-shunted mechanical resonator and plotting such against various resistance values. Where these eigenfrequencies coalesce is the point referred to as the exceptional point and is the foundation for shunting circuit 235 tuning. Determining the exceptional point for the absorption system, i.e., the LR-shunted mechanical resonator may include evaluating, from the coupled second-order differential equations presented above, eigenfrequencies of the LR-shunted mechanical resonator based on a mass, spring constant, and a damping coefficient of the first mechanical resonator, where the exceptional point represents an intersection of the eigenfrequencies. It should be noted that the calculation of the exceptional point for the LR-shunted mechanical resonator may be performed before or after attaching the mechanical resonator to the body 205.

At operation 720, the inductor 340 and resistor 345 values for the shunting circuit 235 are set based on the calculated exceptional point. That is, the controller 240 may set the resistance of the resistor 345 in the shunting circuit 235 to the resistance value associated with the exceptional point as depicted and calculated in FIG. 4. As described above, based on the set resistance value of the shunting circuit 235, the latent absorption of the absorption system 200 is either directed towards perfect reflection or perfect absorption.

In one embodiment, the controller 240 also adjusts the inductor value. Adjusting the inductor value shifts the absorption spectrum peak for the absorption system 200. Accordingly, the controller 240 adjusts the inductor 340 value such that the absorption spectrum peak for an altered absorption (i.e., towards total reflection or total absorption) aligns with an absorption spectrum peak for the passive mechanical resonator.

At operation 730, the shunting circuit 235 generates electricity to totally absorb or totally reflect the flexural wave. That is, the absorption system 200 detects a flexural wave 210 propagating through the body 205. Specifically, the piezoelectric device 230 responds to mechanical stress in the body 205 caused by the flexural wave. The piezoelectric device 230 then generates an electric charge in response to the mechanical stress in the body 205. In this manner, energy is converted from the form of a propagating flexural wave into electrical energy. The absorption system 200 dissipates the electric charge, absorbing the flexural wave. Specifically, the shunting circuit 235 generates an opposite charge in response to the electric charge generated by the piezoelectric device 230, which dissipates the electric charge generated by the piezoelectric device 230. Thus, the absorption system 200 completely or nearly completely absorbs the flexural wave.

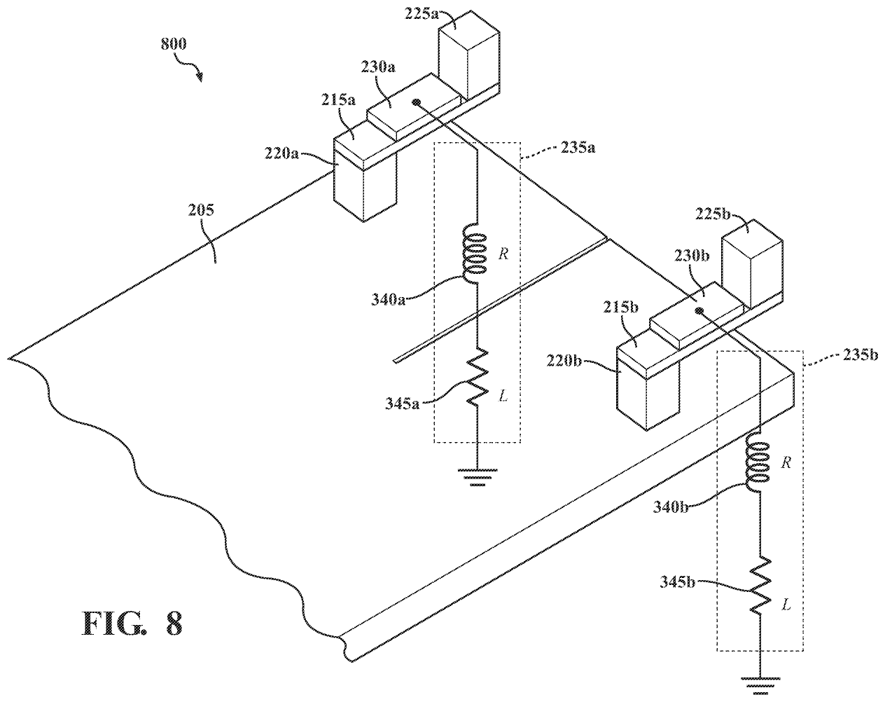

FIG. 8 illustrates one embodiment of the absorption system 800 having multiple mechanical resonators and electrical resonators. That is, in one embodiment the absorption system 800 includes a second mechanical resonator connected to the body 205. As described above, the first mechanical resonator includes a base member 220a coupled to a beam 215a connected to the body 205, the base member 220a maintaining the beam 215a at an elevated position away from the body 205. The first mechanical resonator further includes a rigid mass component 225a attached at a distal end of the beam 215. The second mechanical resonator similarly includes a base member 220b, beam 215b, and rigid mass component 225b. In some examples, the body 205 may include a slit to decouple the two resonators.

To convert the absorption system 200 from absorbing/reflecting less than all of the flexural wave 210 to a total absorber or total reflector, the absorption system 200 further includes an electrical resonator coupled to each mechanical resonator. That is, the absorption system 200 includes a first electrical resonator coupled to the first mechanical resonator and a second electrical resonator coupled to a second mechanical resonator. As described above, each electrical resonator includes a respective piezoelectric device 230a, 230b and respective shunting circuits 235a, 235b with respective inductors 340a, 340b and resistors 345a, 345b. However, in some examples, the second electrical resonator has a different wave absorption coefficient than the first electrical resonator.

As described above, whether or not an electro-mechanical resonator totally reflects or totally absorbs a propagating flexural wave depends on the adjustments made to the resistors 345a, 345b of the respective shunting circuits 235a, 235b. In one example, the different resistors 345a. 345b may be tuned differently such that the respective resonators react differently to propagating waves. For example, the first electrical resonator may be tuned to totally absorb the flexural wave, while the second electrical resonator is tuned to totally reflect the flexural wave. As a specific example, the first resistor 345a may be set to a first resistance value (e.g., 100 ohms from the above example) such that the first system exhibits total reflection of the flexural wave while the second resistor 345b is set to a second resistance value (e.g., 3.6 kiloohms) that is greater than the first resistance such that the second system exhibits total absorption of the flexural wave. In this example of multiple electro-mechanical resonators on the body 205, the method 700 described in FIG. 7 also includes determining the exceptional point for the second LR-shunted mechanical resonator and setting the respective inductor and resonator values to totally absorb or totally reflect the flexural waves.

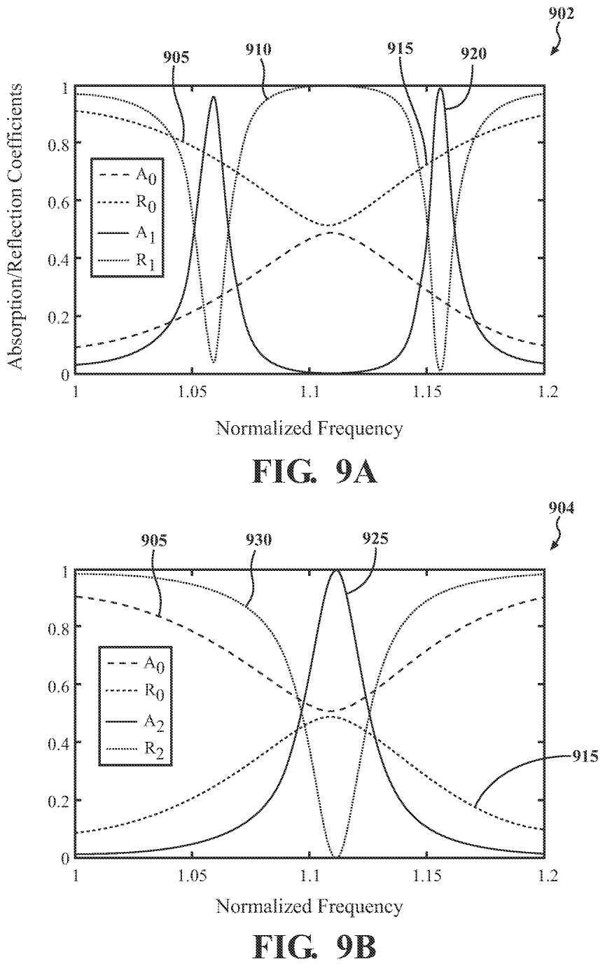

FIGS. 9A and 9B are example graphs 902, 904 depicting absorption spectra of an absorption system 200 tuned towards total reflection and total absorption, respectively. In both FIGS. 9A and 9B, the absorption and reflection coefficients of a passive mechanical resonator (e.g., without any electrical shunting) are depicted as dashed lines 905, 915, respectively. As seen in FIGS. 9A and 9B, a passive mechanical resonator is imperfect in that some portion of a flexural wave 210 is transmitted past the passive mechanical resonator to the rest of the body 205 structure, which can potentially damage the body. As depicted in FIGS. 9A and 9B, the absorption peak for the passive mechanical resonator is about 50% at 1.12 of the normalized frequency.

As described above, based on a calculated exceptional point for the LR-shunted mechanical resonator, the shunting circuit 235 can be tuned to total reflection as denoted by the lines 910, 920 in FIG. 9A or perfect absorption as denoted by the lines 925, 930 in FIG. 9B.

In FIG. 9A, perfect reflection is indicated with the line 920 and the line 910 representing the absorption and reflection spectrum, respectively. Due to the coupling between the electrical and mechanical resonances, two absorption peaks appear in the absorption spectrum, with an absorption valley in between the two peaks. The two absorption peaks correspond to the detuned frequencies before the exceptional point, as shown in FIG. 4. By further tuning the resistance after the exceptional point, a single absorption peak is found in the absorption spectrum, as depicted in FIG. 9B. This single peak is due to the degenerated mode around the exceptional point. In FIG. 9B, perfect absorption is indicated with the line 925 and the line 930 representing the absorption and reflection spectrum, respectively. As described above, the absorption spectrum for either case is much broader than mechanical resonators that are not tuned towards the exceptional point.

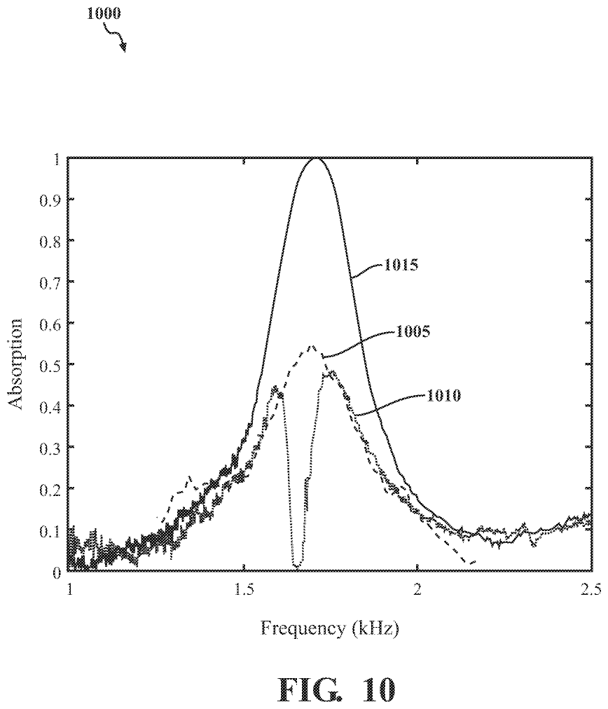

FIG. 10 is an example graph 1000 depicting an observed absorption spectrum of an absorption system 200 that is tuned based on the exceptional point for the LR-shunted mechanical resonator/absorption system. The example graph 1000 shows that shunting an absorption system 200 around the exceptional point of the absorption system 200 tunes an imperfect absorber into an absorption system 200 that totally reflects or totally absorbs a flexural wave. The absorption system 200 under test included a synthetic inductor, as depicted in FIG. 6. An additional resistor 345 was connected to the top lead of the piezoelectric path while the bottom of the piezoelectric path was grounded.

Before executing the validation test, the absorption and reflection performance of the passive mechanical resonator was measured and the shunting circuit 235 was adjusted as described above. The absorption system 200 was then attached to the body 205 at a distance of d=17 mm from the free end of the body 205, as depicted in FIG. 2.

In the test, a shaker was driven by a function generator via a power amplifier to cause a perturbation or excitation upon the absorption system 200. A laser Doppler vibrometer (LDV) or displacement/accelerometer sensor measured the velocity response of the body 205. A computing device acquired data from the data acquisition (DAQ) device associated with measurements of the LDV. Furthermore, the computing device triggered additional perturbations by controlling the function generator.

The measured absorption spectra are shown in FIG. 10. In FIG. 10, a first line 1005 represents the absorption spectrum of a passive absorption system with an open circuit (i.e., no shunting). As seen in FIG. 10, the maximum absorption of a passive system is about 55%.

As described herein, when the piezoelectric device 230 is shunted, the peak absorption can be tuned to either totally reflect or totally absorb any propagating flexural wave. A second line 1010 denotes the absorption system 200, tuned to the calculated exceptional point with the resistance of the resistor set to a small resistance value. In this case, the absorption system 200 is a perfect reflector. The absorption spectrum is split into two parts, with the middle dip reaching zero due to the coupling between the mechanical and electrical resonators before the exceptional point. The absorption spectrum split gradually closes near the exceptional point by increasing the shunting resistance value. Perfect absorption is achieved by tuning this resistor alone, which is illustrated by the third line 1015 in FIG. 10. The closing of the spectrum by increasing the resistance value is due to the coalescing of the eigenmodes after the exceptional point. As such, FIG. 10 provides experimental data indicating that an imperfectly absorbing system can be tuned to perfect absorption or perfect reflection by adjusting the resistance value of a shunting circuit 235 about an exceptional point for a mechanical resonator.

Note that in FIG. 10, the maximum absorption peak for the tuned absorption system 200 is shifted with regard to the maximum absorption peak for the latent absorption of the passive mechanical resonator. As described above, the inductor 340 of the shunting circuit 235 may be adjusted to align the frequency peak of an altered absorption spectrum with the frequency peak of the passive mechanical resonator's latent absorption spectrum.

As such, the absorption system 200 of the present specification may realize multiple functions, such as perfect reflection and perfect absorption for a latently imperfect absorber. Such an absorption system 200 would be used in a number of applications, including wave filtering and vibration isolation/suppression devices for practical engineering applications, as well as enhanced sensitivity for structural health monitoring and bio-sensing, among others.

Detailed embodiments are disclosed herein. However, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-10, but the embodiments are not limited to the illustrated structure or application.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises all the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

Generally, modules as used herein include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object-oriented programming language such as Java™, Smalltalk, C++ or the like, and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A system, comprising:
a first mechanical resonator having a beam connected to a body that is subject to a flexural wave, the first mechanical resonator has a latent absorption; and
a first electrical resonator comprising:
a piezoelectric device, bonded to the beam, that generates electricity in response to the flexural wave propagating through the body; and
a shunting circuit, connected to the piezoelectric device and tuned based on a calculated exceptional point for the system, that:
alters an absorption of the first mechanical resonator; and
controls a voltage and current shunted to the piezoelectric device to absorb the flexural wave.

2. The system of claim 1, wherein the shunting circuit comprises an inductor and a resistor connected in series that increase a wave absorption coefficient of the first electrical resonator, the inductor and resistor tuned to the calculated exceptional point for the system.

3. The system of claim 2, wherein the resistor having a first resistance value alters the system to totally reflect the flexural wave.

4. The system of claim 3, wherein the resistor having a second resistance value that is greater than the first resistance value alters the system to totally absorb the flexural wave.

5. The system of claim 2, wherein the inductor is tuned to align a frequency peak of an altered absorption spectrum with a frequency peak of a latent absorption spectrum.

6. The system of claim 1, further comprising:
a second mechanical resonator connected to the body; and
a second electrical resonator coupled to the second mechanical resonator, wherein the second electrical resonator has a different wave absorption coefficient than the first electrical resonator.

7. The system of claim 6, wherein the first electrical resonator is tuned to totally absorb the flexural wave and the second electrical resonator is tuned to totally reflect the flexural wave.

8. A system, comprising:
a first mechanical resonator having a beam connected to a body that is subject to a flexural wave; and
a first electrical resonator, comprising:
a piezoelectric device, bonded to the beam, that generates electricity in response to the flexural wave propagating through the body; and
a shunting circuit, connected to the piezoelectric device and tuned based on a calculated exceptional point for the system, that:
alters an absorption of the first mechanical resonator towards perfect absorption or perfect reflection; and
controls a voltage and current shunted to the piezoelectric device to absorb the flexural wave.

9. The system of claim 8, wherein the shunting circuit comprises an inductor and a resistor connected in series that increase a wave absorption coefficient of the first electrical resonator, the inductor and resistor tuned to the calculated exceptional point for the system.

10. The system of claim 9, wherein the resistor having a first resistance value alters the system to totally reflect the flexural wave.

11. The system of claim 10, wherein the resistor having a second resistance value that is greater than the first resistance value alters the system to totally absorb the flexural wave.

12. The system of claim 9, wherein the inductor is tuned to align a frequency peak of an altered absorption spectrum with a frequency peak of a latent absorption spectrum.

13. The system of claim 8, further comprising:
a second mechanical resonator connected to the body; and
a second electrical resonator coupled to the second mechanical resonator, wherein the second electrical resonator has a different wave absorption coefficient than the first electrical resonator.

14. The system of claim 13, wherein the first electrical resonator is tuned to totally absorb the flexural wave and the second electrical resonator is tuned to totally reflect the flexural wave.

15. A method, comprising:
calculating an exceptional point for a first system comprising a first mechanical resonator shunted by a first electrical resonator, the first system placed on a body that is subject to a flexural wave, the first mechanical resonator has a latent absorption;
altering a wave absorption coefficient of the first electrical resonator by setting inductor and resistor values of a shunting circuit of the first electrical resonator based on a calculated exceptional point; and
generating, via the shunting circuit, electricity to totally absorb or totally reflect the flexural wave in the body.

16. The method of claim 15, wherein:
calculating the exceptional point for the first system comprises evaluating, from coupled second-order differential equations, eigenfrequencies of the first mechanical resonator based on a mass, a spring constant, and a damping coefficient of the first mechanical resonator; and
the calculated exceptional point represents a coalescence of eigenfrequencies.

17. The method of claim 15, wherein setting inductor and resistor values based on the calculated exceptional point comprises setting a resistor value to a first resistance value to totally reflect the flexural wave.

18. The method of claim 17, wherein setting inductor and resistor values based on the calculated exceptional point comprises setting a resistor value to a second resistance value that is greater than the first resistance value to totally absorb the flexural wave.

19. The method of claim 15, further comprising:
calculating an exceptional point for a second system placed on the body; and
altering a wave absorption coefficient of a second electrical resonator coupled to a second mechanical resonator of the second system by setting inductor and resistor values of a shunting circuit of the second electrical resonator based on the exceptional point for the second system.

20. The method of claim 15, wherein setting inductor and resistor values comprises setting an inductor value to align a frequency peak of an altered absorption spectrum with a frequency peak of a latent absorption spectrum.
